(19) United States
(12) Patent Application Publication
(10) Pub. No.: US 2025/0232104 A1
(43) Pub. Date: Jul. 17, 2025

(54) WAFER-LEVEL DESIGN, MANUFACTURING, AND INTEGRATION METHODS OF SYSTEM ON WAFER

(71) Applicant: Northwestern Polytechnical University, Shaanxi (CN)

(72) Inventors: Tao Ye, Shaanxi (CN); Xinrui Zhang, Shaanxi (CN)

(21) Appl. No.: 18/897,952

(22) Filed: Sep. 26, 2024

(30) Foreign Application Priority Data
Jan. 16, 2024 (CN) 202410058771X

(51) Int. Cl. G06F 30/392

(52) U.S. Cl. CPC G06F 30/392

(57) ABSTRACT

The present disclosure discloses wafer-level design, manufacturing, and integration methods of system on wafer (SoW). Through similar integrated circuit (IC) processes, the heterogeneous functional structures of devices (dies) are prepared on a wafer (layer); then the multi-wafers with different functional structures are bonded to form high density devices (dies) with complete functions; and the wafer-level functions are reconfigured to form the intelligent microsystem (SoW). Based on the existing semiconductor manufacturing and packaging technology, the functional/sensor devices (dies), electrical interconnect layers, back-end dies, and heat dissipation modules are integrated to form the SoW, which can realize the functional reconfiguration and intelligent collaborative control under the collaboration of multifunctional dies within the SoW, and dramatically improve the integration and function density of the SoW, to realize intelligentization.

### CROSS-REFERENCE TO RELATED APPLICATION

The present disclosure claims priority to Chinese patent Application No. 202410058771X, filed with the Chinese Patent Office on Jan. 16, 2024, and entitled “WAFER-LEVEL DESIGN, MANUFACTURING, AND INTEGRATION METHODS OF SYSTEM ON WAFER”, the entire contents of which are incorporated herein by reference.

### TECHNICAL FIELD

The present disclosure belongs to the field of system on wafer, and more specifically relates to the wafer-level design, manufacturing, and integration methods of system on wafer.

### BACKGROUND ART

With the rapid development of the integrated circuit (IC) industry, the advanced process node gradually approaches the limitation of mainstream silicon-based lithography technique, and Moore's Law may fail progressively. In response to the technical difficulty that Moore's Law can no longer be used, academia and industry mainly complement and extend Moore's Law by adopting chip-level integration technology of system on chip (SoC) and wafer-level integration technology of system on wafer (SoW).

The chip-level integration technology of system on chip (SoC) essentially integrates chips with different functions manufactured by the same process together by IC design. Subject to the semiconductor manufacturing technology and the semiconductor material performance, SoC mostly relies on interposer to realize heterogeneous integration of multiple functional chips, which makes it difficult to form a powerful independent system. Compared with the discrete integration of each chip relying on the interposer in SoC, a base wafer used in the wafer-level integration technology of system on wafer (SoW) is a semiconductor wafer with standard sizes, on which the active dies/passive dies can be processed and prepared directly. It combines with RDL (re-distributed layer), TSV (through silicon via), wafer-level bonding, and other processes, of the whole wafer to realize the electrical interconnection and co-wafer integration with the large-scale computation dies, storage dies, and heat dissipation modules, etc., and to build the SoW with high integration and high computing capacity.

At present, the sample cases of large-scale SoW are rare, and the prior cases of the SoW are still limited to the discrete integration of the SoC technology. Only part of the simple devices (dies) are prepared by the whole surface processing technology of the semiconductor wafer, which lacks the practical application to the whole wafer processing technology in the preparation of multiple devices (dies). If some advanced concepts can be adopted in the SoW, e.g., similar IC processes are used in co-wafer preparation of the dies with heterogeneous functions and structures, multi-wafers are bonded to form devices (dies) with high density, and the wafer-level functions reconfigure to form the intelligent microsystem (SoW). If significant advantages of the wafer-level interconnections (TSV and RDL) can be adopted, such as high bandwidth, low latency, and lower power consumption, the functional devices of sensor and radio frequency, and the back-end dies for computing, storage, and communication can be integrated into the form of same-size multi-wafers, to break “ceiling effect” of the microsystem functions caused by the simple “stacked” inefficient integration of the prior same dies, and to reconfigure a multi-function integrated intelligent SoW.

The present disclosure discloses wafer-level design, manufacturing, and integration methods of SoW. Based on the concepts that similar IC processes are used in co-wafer preparation for the dies with heterogeneous functions and structures, the multi-wafers are bonded to form devices (dies) with high density, and the wafer-level functions reconfigure to form the intelligent microsystem (SoW), etc. Based on the prior semiconductor manufacturing and packaging technologies, the functional/sensor devices (dies), electrical interconnect layers, back-end dies, and heat dissipation modules are integrated into the SoW. In the above SoW, the signal transmission and energy transmission between the back-end dies and the functional/sensor devices (dies) can be realized after the back-end dies send logic control instructions. After the back-end dies are sequentially combined with the functional/sensor devices (die), different functional/sensor devices (dies) will reconfigure new functional performances under commands from different back-end dies, which realize the localized function reconfiguration under the collaboration of multiple devices (dies) within SoW, and dramatically improve the integration and function density of the SoW, to realize intelligentization.

### SUMMARY

In response to the deficiencies or improvement requirements of the prior art, the present disclosure discloses wafer-level design, manufacturing, and integration methods of SoW, which improves the integration of the back-end dies (CPU (central processing unit), GPU (graphics processing unit), MCU (microprogrammed control unit), etc.) and the functional/sensor devices (dies). The back-end dies send out commands to regulate functional performances of the functional/sensor devices (dies), which realize the function reconfiguration under collaboration of multiple devices (dies) within SoW, and dramatically improves the integration and function density of the multiple dies of the prior SoW, to realize the intelligentization.

In order to overcome the deficiencies in the prior art, the present disclosure provides the wafer-level design, manufacturing, and integration methods of SoW, wherein the SoW is of a stacked structure of multi-wafer arrays with the same size. The wafer-level design, manufacturing, and integration methods of the SoW includes:

an integrated functional/sensor devices (dies) bonding with multiple wafers, including a wafer (dies layer) with outer functional layer of functional/sensor devices (dies), a wafer (dies layer) with middle functional layer of the functional/sensor devices (dies), and a wafer (dies layer) with inner functional layer of the functional/sensor devices (dies); an electrical interconnect layer, including RDLs on front and back surfaces and partitioned TSV arrays interconnect between upper and lower surfaces of the electrical interconnect layer; a back-end dies layer, including dies for computing, communication and storage, and power supply ports; and a heat dissipation module layer, including serpentine liquid cooling channels, liquid cooling inlet/outlet ports, and a recessed patterned heat dissipation groove complementary on the back-end dies layer.

Furthermore, after the outer functional layer, the middle functional layer, and the inner functional layer of the functional/sensor devices (dies) are prepared on different wafers (in layers), the structures of different functional/sensor devices (dies) in different wafers (layers) are co-wafer prepared by similar IC processes, which simplifies the process flow. Meanwhile, since some functional/sensor devices (dies) are of structures that are difficult to be prepared on the wafer, these types of devices (dies) in the traditional integration method are discretely integrated on an interposer, wherein these types of devices (dies) have lower integration and function density. The preparation for the functional layers on different wafers (layers) with IC processes can solve the problem that it is difficult to realize the wafer-level design, manufacturing, and integration in the SoW by preparing devices (dies) on multi-wafers, wherein each layer (wafer) has partial functions or structures of the complete device (die); and then it realizes the integration of functions and structures through a multi-layer interconnection method to form the complete devices (dies), which can be further integrated with other devices (dies) prepared with similar method into an intelligent SoW.

Furthermore, a layout design in wafers (layers) of the outer functional layer, the middle functional layer, and the inner functional layer of the functional/sensor devices (dies) is not limited to three wafers (layers), wherein the number of functional wafers (layers) is different according to a complexity of functions or a complexity of an internal structure of different functional/sensor devices (dies); and at the same time, the number of functional wafers (layers) can be designed differentially according to differences of preparation difficulty of an internal structure of the functional/sensor devices (dies).

Furthermore, a structure on only one of the outer functional wafer (layer), the middle functional wafer (layer), and the inner functional wafer (layer) of the functional/sensor devices (dies) cannot realize complete functions of devices (dies); and complete functions of devices are realized by electrically connecting the partial structures/devices in the outer functional layer (wafer), the middle functional layer (wafer), and the inner functional layer (wafer) via bonding by TSV, RDL, Bumps, and solder ball reflow soldering, etc.

Furthermore, the outer functional wafer (layer) of the functional/sensor devices (dies) is provided with external structures of a plurality of functional/sensor devices (dies), including, but not limited to functional/sensor structures (parts) that have information interaction or energy conversion/transfer with the external environment, which include, but are not limited to a sensitive layer of the sensor dies (temperature sensor, pressure sensor, humidity sensor, light sensor, acceleration sensor, etc.); or partial other structures of the functional/sensor devices (dies).

Furthermore, the middle functional wafer (layer) of the functional/sensor devices (dies) includes, but is not limited to a critical structure layer (wafer) of the functional/sensor devices (dies) for processing electrical signals generated by the outer functional layer (wafer), which includes analog signal processing circuits, such as an amplifier, a filter, an oscillator, etc.; digital signal processing circuits, such as a logic gate, a memory, a counter, etc.; or partial other structures of the functional/sensor devices (dies).

Furthermore, the inner functional wafer (layer) of the functional/sensor devices (dies) is the other structure required to realize functions besides the outer functional layer (wafer) and middle functional layer (wafer), and is taken as a complement to a functional layer (wafer) structure, including but not limited to structures that cannot be co-wafer prepared due to the incompatibility of preparation processes between the outer functional layer (wafer) and the middle functional layer (wafer).

Furthermore, on the wafers including the outer functional layer (wafer), the middle functional layer (wafer), and the inner functional layer (wafer) of the functional/sensor devices (dies), dummy dies are arranged on four vertexes furthest away from a geometric center of the wafer. There is no effective functional layer in the dummy dies. During the preparation process of the whole wafer, the dummy dies are configured to balance internal forces generated at the position where the wafer is warped seriously after the whole wafer is provided with modules/devices (dies) in different regions, wherein the modules/devices (dies) are similar but not the same, to improve the structure stability of the whole wafer. Meanwhile, the dummy dies provide flat boding sites with a large area when the multi-array wafers bonding, which is beneficial for the bonding flatness of the resultant SoW.

Furthermore, the electrical interconnect layer (wafer) includes RDLs on upper and lower surfaces and TSV arrays, wherein the RDLs on double surfaces are configured to electrically interconnect the double surfaces of the wafer horizontally and fan out fine circuit contacts of dies to provide more pins and larger I/O (input/output) contact spacing. The TSV arrays realize electrical interconnections in a vertical direction between two surfaces, and an electrical interconnection of any two points in the wafer on the electrical interconnect layer can be realized (through TSV arrays) in conjunction with the RDLs on the double surfaces.

Furthermore, the back-end dies include but are not limited to CPU, GPU, MCU, communication dies, etc., and the back-end dies are configured as main controlling dies to send commands via the electrical interconnect layer (wafer). The power supply ports provide different voltage values according to the operating voltages of different devices (dies). Different functional/sensor devices (dies) can achieve different functions under different commands from different back-end dies, which realize reconfiguration of functions under collaboration of multiple devices (dies) within SoW, and dramatically improves the function density.

Furthermore, each region on the outer functional layer (wafer), the middle functional layer (wafer), and the inner functional layer (wafer) of the functional/sensor devices (dies) is not necessarily provided with the devices. The simple and complex functional/sensor devices (dies) simultaneously exist in the SoW, wherein the simple functional/sensor devices (dies) need fewer functional layers (wafers), and the complex functional/sensor devices (dies) need more functional layers (wafers). In order to ensure that the complex functional/sensor devices (dies) are completely prepared, the SoW has a large number of functional wafers (layers). In the regions for the simple functional/sensor devices (dies), multiple functional layers (wafers) may not be provided within the devices.

Furthermore, the heat dissipation module wafer (layer) includes connectors for the serpentine liquid cooling channels and the liquid inlet/outlet ports, and the recessed patterned groove complementary on the back-end dies, wherein the liquid cooling channel connectors include liquid inlet ports and liquid outlet ports, in which a low-temperature liquid flows through to cool down the high temperature generated by the operation of back-end dies.

Furthermore, bonding and interconnection of multi-array wafers include but are not limited to solder balls, UBM (under bump metallization), EMC (epoxy molding compound), etc. After multiple wafers are aligned by alignment marks, solder balls on bottom of an upper wafer are stably interconnected with bonding pads on upper surface of a lower wafer electrically and mechanically via reflow soldering, wherein surfaces of the wafers need to perform UBM before planting the solder balls to increase adhesion of a tin solder to the wafers and to prevent tin diffusing into the wafers.

The foregoing summary of the present disclosure is only to illustrate the principles and functions of the present disclosure, and is not intended to limit the present disclosure. Any person familiar with the technology may modify or change the contents of the present disclosure without departing from the spirit and scope of the present disclosure. Therefore, any equivalent modification or change made by a person with ordinary knowledge in the technical art without deviating from the spirit and technical ideas disclosed by the present disclosure shall still be covered by the claims of the present disclosure. Other features in the specification of the present disclosure will be easily understood by the following contents.

### BRIEF DESCRIPTION OF DRAWINGS

FIG. 1 shows a schematic structure diagram of the wafer on the outer functional layer of the functional/sensor devices (dies) in the embodiment of the present disclosure.

FIG. 2 shows a cross-sectional structure schematic diagram of the wafer on the outer functional layer of the functional/sensor devices (dies) in the embodiment of the present disclosure.

FIG. 3 shows a schematic structure diagram of the wafer on the middle functional layer of the functional/sensor devices (dies) in the embodiment of the present disclosure.

FIG. 4 shows a cross-sectional structure schematic diagram of the wafer on the middle functional layer of the functional/sensor devices (dies) in the embodiment of the present disclosure.

FIG. 5 shows a schematic structure diagram of the wafer on the inner functional layer of the functional/sensor devices (dies) in the embodiment of the present disclosure.

FIG. 6 shows a cross-sectional structure schematic diagram of the wafer on the inner functional layer of the functional/sensor devices (dies) in the embodiment of the present disclosure.

FIG. 7 shows a schematic structure diagram of TSV arrays of the electrical interconnect wafer in the SoW of the embodiment of the present disclosure.

FIG. 8 shows a schematic structure diagram of RDLs on the surface of the electrical interconnect wafer in the SoW of the embodiment of the present disclosure.

FIG. 9 shows a cross-sectional structure schematic diagram of electrical interconnect layer in the SoW of the embodiment of the present disclosure.

FIG. 10 shows a schematic structure diagram of the wafer on the back-end dies layer in the embodiment of the present disclosure.

FIG. 11 shows a cross-sectional structure schematic diagram of the wafer on the back-end dies layer in the embodiment of the present disclosure.

FIG. 12 shows a schematic structure diagram of the wafer on the heat dissipation module layer in the embodiment of the present disclosure.

FIG. 13 shows a cross-sectional structure schematic diagram of the wafer on the heat dissipation module layer in the embodiment of the present disclosure.

FIG. 14 shows a cross-sectional structure schematic diagram of the SoW in the embodiment of the present disclosure.

### REFERENCE NUMBERS

1—wafer on the outer functional layer of the functional/sensor devices (dies), 2—wafer on the middle functional layer of the functional/sensor devices (dies), 3—wafer on the inner functional layer of the functional/sensor devices (dies), 4—electrical interconnect wafer, 5—wafer on the back—end die layer, 6—wafer on the heat dissipation module layer, 7—dummy dies, 8—outer functional layer of the functional/sensor devices (dies), 9—TSV in the functional/sensor devices (dies), 10—middle functional layer of the functional/sensor devices (dies), 11—RDL on the surface of the middle functional layer of the functional/sensor devices (dies), 12—inner functional layer of the functional/sensor devices (dies), 13—RDL on the surface of the inner functional layer of the functional/sensor devices (dies), 14—TSV arrays of the wafer on the electrical interconnect layer, 15—RDLs on the surface of the wafer on the electrical interconnect layer, 16—back—end dies, 17—RDLs on the surface of the back-end die layer, 18—liquid inlet port of the liquid cooling channel, 19—liquid outlet port of the liquid cooling channel, 20—recessed patterned groove complementary on the back-end die on the heat dissipation module, 21—plastic fill of the reflow soldering on the wafer interface, 22—interface bonding the heat dissipation module to the back-end die, 23—under bump metallization (UBM), 24—solder ball, and 25—power supply port of the back-end die.

### DETAILED DESCRIPTION OF EMBODIMENTS

In order to better understand the technical solutions by a person skilled in the field, the technical solutions in the embodiments of the present disclosure will be clearly and completely described in conjunction with the drawings in the embodiments of the present disclosure. It is clear that the embodiments described are partial embodiments of the present disclosure, but not all of the embodiments. In conjunction with the embodiments of the present disclosure, all other embodiments obtained by a person of ordinary skill in the field without inventive efforts shall fall within the scope of protection of the present disclosure.

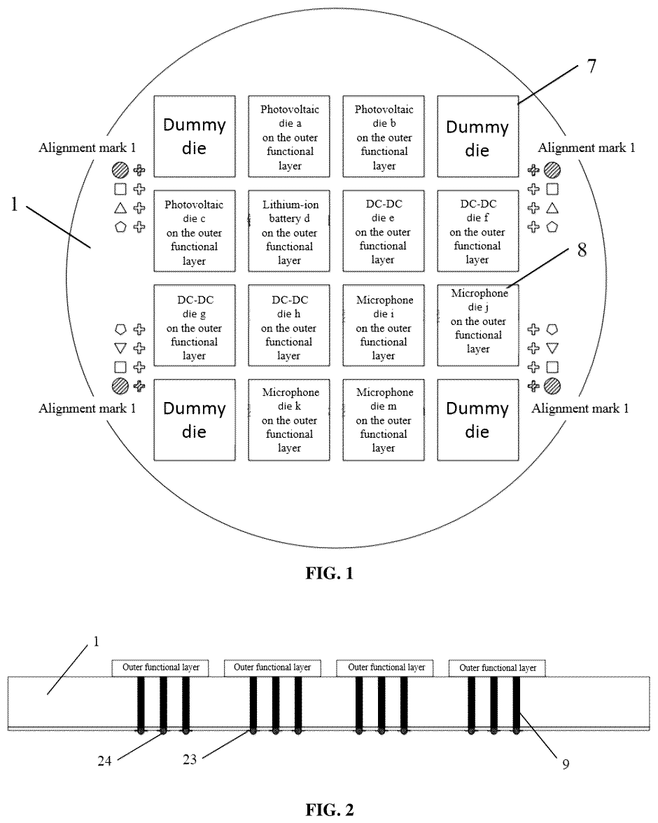

As shown in FIG. 1, FIG. 1 shows the schematic structure diagram of the wafer on the outer functional layer of the functional/sensor devices (dies) in the wafer-level design, manufacturing, and integration methods of the SoW. As for wafer 1 on the outer functional layer of the functional/sensor devices (dies), the wafer is provided with the outer functional layers of different devices (dies) in different regions by adopting a similar IC processes. It includes, but is not limited to semiconductor structures that have information interaction or energy conversion/transfer with the surrounding environment, such as a sensitive layer of the sensor dies (temperature sensor, pressure sensor, humidity sensor, light sensor, acceleration sensor, etc.); and includes, but is not limited to the positive electrode of the energy storage device and positive charge collector, etc. The reference sign 7 represents the dummy dies, which balance the large internal force generated when the whole wafer is provided with modules/devices that are similar but not the same in different regions, and provide flat boding sites with large areas when the multi-array wafers bond. The outer functional layer (wafer) 8 of dies is the outer functional layer of different functional/sensor devices (dies) co-wafer prepared in different regions in the wafer. In the embodiment, the dies a-c on the outer functional layer of the wafer 1 are the light-sensitive layers and top electrodes of photovoltaic cells. For the perovskite solar cell, the light-sensitive layer includes an anti-reflective layer, a top electrode layer, a hole transport layer, an electron transport layer, and a perovskite light-absorbing layer. For the silicon solar cell and gallium arsenide solar cell, the light-sensitive layer includes an anti-reflective layer, a top electrode layer, an N-type semiconductor layer, a tunneling layer, and a P-type semiconductor layer. In the embodiment, the die d of the wafer 1 on the outer functional layer is a positive electrode and a positive charge collector of a lithium-ion battery, wherein the positive electrode can be made of lithium iron phosphate, and the positive charge collector can be made of aluminum. In the embodiment, the dies e-h on the outer functional layer of the wafer 1 includes a resistance, an inductor, a capacitor, and other devices in the photovoltaic DC-DC (direct current to direct current) peripheral circuit. In the embodiment, the dies i-m on the outer functional layer are the housings of the MEMS (Micro-Electro-Mechanical System) microphone. The housings provide the inner cavity in the microphone, and is configured to protect the backplate with sound holes and the internal vibratory diaphragm, to prevent the outside world from connecting to the upper electrode in the backplate.

As shown in FIG. 2, FIG. 2 shows the cross-section structure schematic diagram of the wafer on the outer functional layer of the functional/sensor devices (dies) in the wafer-level design, manufacturing, and integration methods of the SoW. In the embodiment, label 9 is TSV vertically interconnecting this wafer to realize the electrical interconnection between the outer functional layer and the wafer at different sides. The reference sign 23 represents the UBM to increase the adhesion of tin solder to the wafer and to prevent tin diffusing into the wafer. The solder ball 24 is soldered in the reflow soldering method to realize the electrical and mechanical interconnection with the wafer on the middle functional layer of the functional/sensor devices (dies).

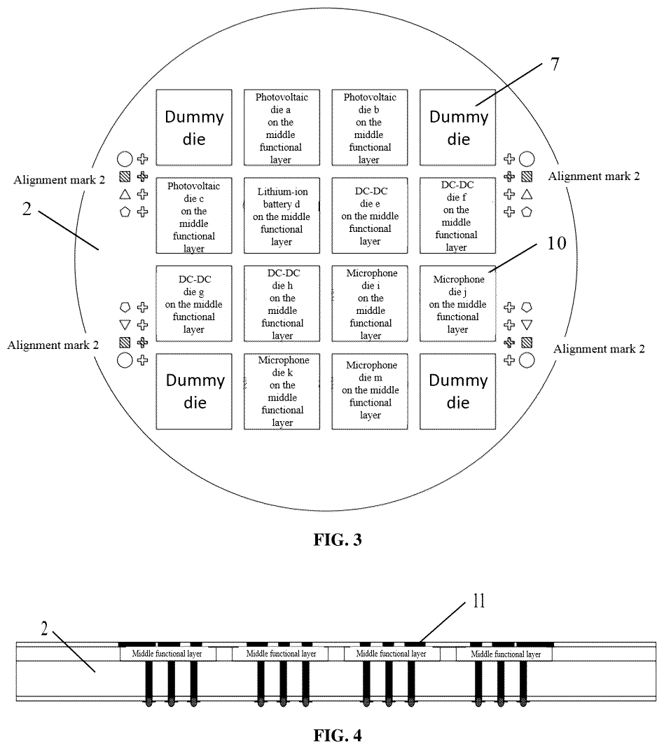

As shown in FIG. 3, FIG. 3 shows the schematic structure diagram of the wafer on the middle functional layer of the functional/sensor devices (dies) in the wafer-level design, manufacturing, and integration methods of the SoW. On wafer 2 on the middle functional layer of the functional/sensor devices (dies), the middle functional layers of different devices are prepared by depositing in different regions by adopting similar IC processes. In the embodiment, the dies a-c on the middle functional layer of the wafer 2 are the bottom electrode layers of the photovoltaic cells. After being exposed to the light, the charge carriers generated by the light-sensitive layer of the wafer 1 on the functional layer of the functional/sensor devices (dies) are transported to the wafer 2 on the middle functional layer of the functional/sensor devices (dies) by the TSV 9 in the functional/sensor device (die). In the embodiment, the die d of the wafer 2 on the middle functional layer is a separator for lithium-ion energy storage die, which can be made of a polyolefin porous film. In the embodiment, the dies e-h on the middle functional layer of the wafer 2 are the amplifier, filter, oscillator, or other analog signal devices in the energy-management DC-DC die, whose operating parameters ranges correspond to the threshold range of the output voltage/current of the die a and the threshold range of the output voltage/current of the die c of the wafer 1. In the embodiment, the dies i-m on the middle functional layer of the wafer 2 are the backplate and the electrode in the MEMS microphone with the sound holes, wherein the sound holes are configured to conduct external acoustic signals into the inner cavity of the microphone to lead to the vibration of the vibrating diaphragm. The electrode conducts an external circuit to charge the backplate and the vibrating diaphragm, to form a capacitor therebetween.

As shown in FIG. 4, FIG. 4 shows the cross-section structure schematic diagram of the wafer on the middle functional layer of the functional/sensor devices (dies) in the wafer-level design, manufacturing, and integration methods of the SoW. In the embodiment, the reference sign 11 represents the RDL on the surface of the middle functional layer (wafer) of the functional/sensor devices (dies), wherein the position of the bonding pad on the RDL layer correspondingly coincides with the position of the solder ball 24 in the wafer 1 on the outer functional layer of the functional/sensor devices (dies).

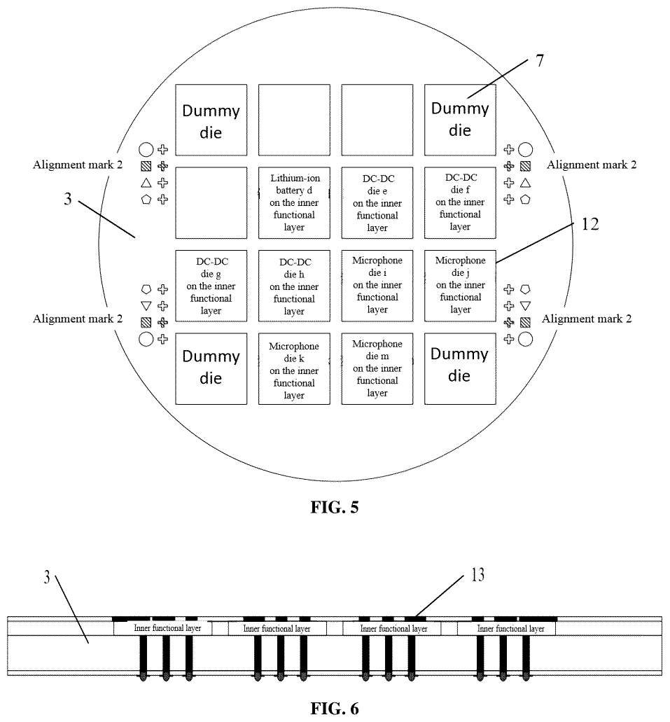

As shown in FIG. 5, FIG. 5 shows the schematic structure diagram of the wafer on the inner functional layer of the functional/sensor devices (dies) in the wafer-level design, manufacturing, and integration methods of the SoW. On wafer 3 of the functional/sensor devices (dies), the inner functional layers of different dies are prepared by adopting similar IC preparation processes in different regions. In the embodiment, the die d of the wafer 3 on the inner functional layer (wafer) is a negative electrode and negative charge collector of the lithium-ion battery, wherein the negative electrode can be made of graphite, and the negative charge collector can be made of copper. The electrolyte is injected at the time when the outer wafer 1, middle wafer 2, and inner wafer 3 are bonding, which can be made from dissolving the carbonate-ester-based organic solvent of the lithium salt. In the embodiment. The dies e-h on the wafer 3 on the inner functional layer are provided with the logic gate, memory, counter, or other circuit devices for processing digital signal, which are configured to accomplish the processing and modulation of the digital signal in the DC-DC circuits, wherein the operating range corresponds to the threshold range of the output voltage/current of the dies a-c on the wafer 1 on the outer functional layer (wafer). In the embodiment, the dies i-m on the inner functional layer are the vibrating diaphragms in the inner cavity of the MEMS microphones. After the external acoustic signal is applied through the sound holes, the vibrating diaphragms are vibrated, to change the capacitor values between the vibrating diaphragms and the backplates. After the external circuit charges the parallel capacitors, which consist of the backplates and the vibrating diaphragms, two electrode plates have the corresponding quantities of electric charge. When the sound wave is transmitted to the vibrating diaphragm, the vibrating diaphragm is vibrated, so that the capacitor value of the parallel capacitor is changed. The external circuit processes and transmits the changed electrical signal, and finally convert the sound signal to the electrical signal.

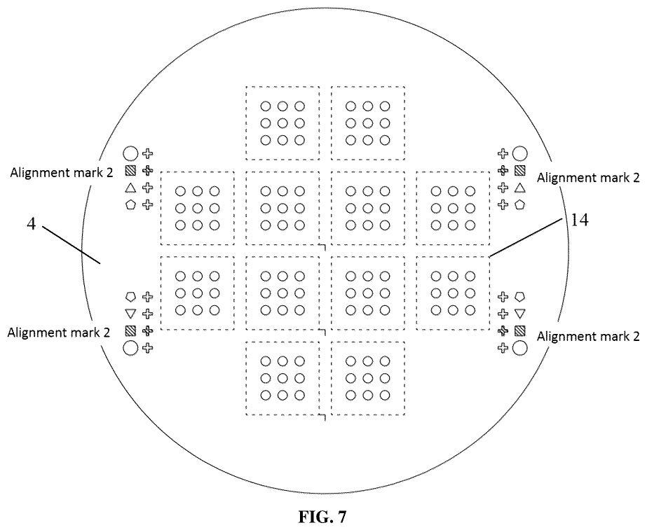

As shown in FIG. 6, FIG. 6 shows the cross-section structure schematic diagram of the wafer on the inner functional layer of the functional/sensor devices (dies) in the wafer-level design, manufacturing, and integration methods of the SoW. The reference sign 13 represents the RDL on the surface of the middle functional layer of the functional/sensor devices (dies), wherein the position of the bonding pad on the RDL layer correspondingly coincides with the position of the solder ball in the wafer 2 on the outer functional layer of the functional/sensor devices (dies). In the embodiment, the number of layers of the RDLs is larger than or equal to 4.

As shown in FIG. 7, FIG. 7 shows the schematic structure diagram of TSV arrays of the wafer on the electrical interconnect layer in the wafer-level design, manufacturing, and integration methods of the SoW. As for the wafer 4 on the electrical interconnect layer, the reference sign 14 represents the TSV array located inside the wafer, which passes through the upper and lower surfaces of the wafer. After processing steps of adhesive coating, photolithography, deep reactive ion etching (DRIE), growth of insulating and blocking layers on the inner wall of the holes by the thermal oxidation process, deposition of seed and adhesion layers in the holes by the magnetron sputtering (MS), electroplating-filling of conductive metals, and chemical-mechanical polishing (CMP) on the front and back surfaces of the wafer, etc., a plurality of different regions on the whole wafer are provided with the TSV array 14. In the embodiment, the diameter of the TSV ranges from 25-50 μm; the depth of TSV is 300±50 μm; the spacing of TSV is 40±5 μm; the seed layer and the adhesion layer are Ti/Cu; and the plating filling metal material is copper.

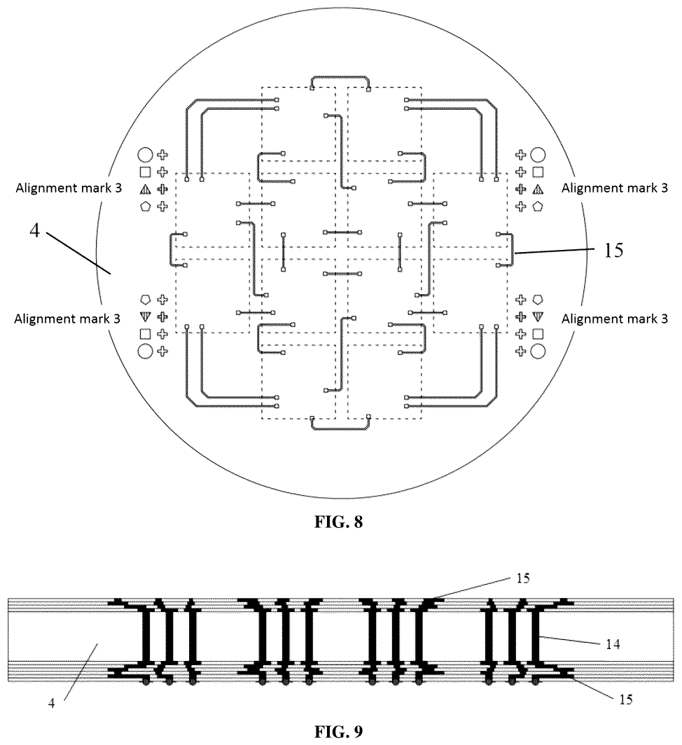

As shown in FIG. 8, FIG. 8 shows the schematic structure diagram of RDLs on the surface of the wafer on the electrical interconnect layer in the wafer-level design, manufacturing, and integration methods of the SoW. As for the wafer 4 on the electrical interconnect layer, the reference sign 15 represents the conductive circuit on the upper and lower surfaces of the wafer.

As shown in FIG. 9, FIG. 9 shows the cross-section structure schematic diagram of the electrical interconnect layer (wafer) in the SoW in the wafer-level design, manufacturing, and integration methods of the SoW. In the embodiment, the positions of the bonding pads in the conductive circuit on the upper and lower surfaces separately correspond to the positions of the solder balls of the RDLs 13 on the wafer 3 of the inner functional layer (wafer) of the functional/sensor devices (dies) and the RDLs 17 on the surface of the back-end die layer in the wafer 5 on the back-end dies layer. The RDLs on the upper and lower surfaces of the wafer 4 on the electrical interconnect layer (wafer) is prepared by the gluing, photolithography (multiple times of overlay), thermo-oxidative growth of insulating layer, chemical-mechanical polishing (CMP) on front and back surfaces, photolithography of RDL patterns, electroplating of conductive metal, and CMP on front and back surfaces, wherein the metal conductive material of the RDLs is copper.

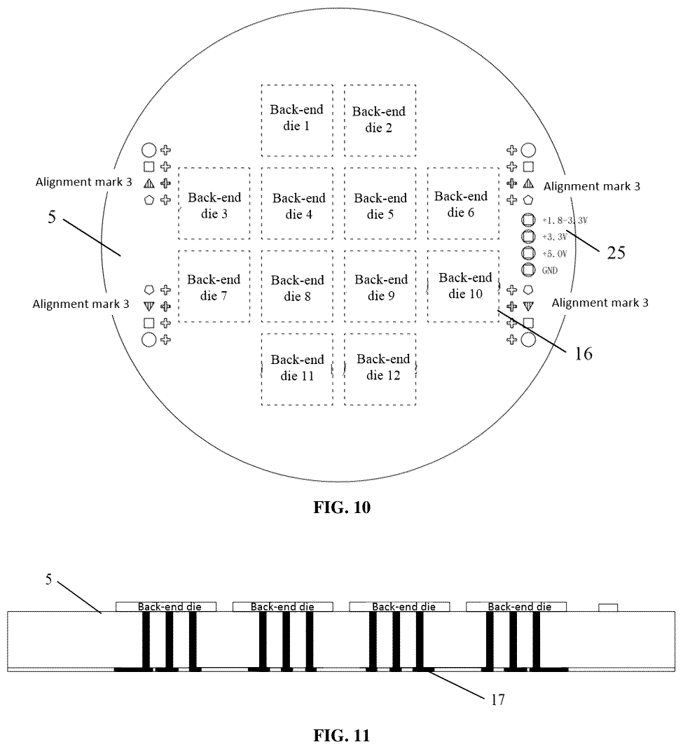

As shown in FIG. 10, FIG. 10 shows the schematic structure diagram of the wafer on the back-end dies layer (wafer) in the wafer-level design, manufacturing, and integration methods of the SoW.

As shown in FIG. 11, FIG. 11 shows the cross-sectional schematic diagram of the wafer on the back-end dies layer (wafer) in the wafer-level design, manufacturing, and integration methods of the SoW. The wafer 5 on the back-end dies layer bonds or is provided with a plurality of dies, and the power supply port 25 of the back-end die supplies power for the dies thereon. The back-end dies 1-3 are the photovoltaic control MCUs, which control the DC-DC energy management dies e-h to track and control the output power of the photocurrent and photovoltage from the photovoltaic devices a-c, and storage the energy converted by the photovoltaic devices a-c into the energy storage device d by the DC-DC energy management circuits e-h. The back-end dies 4-5 are the output power control dies of the energy storage device, wherein the electric energy of the energy storage battery is applied for the operation of other devices or dies within the SoW under commands from the back-end die 4. The back-end dies 6-8 are the ASIC (application specific integrated circuit) dies for the microphones, which are used to realize the amplification, analog-digital conversion, filtering, noise reduction, and other processes for the signals processing, and also used for the transmission and storage for the signals, to realize the conversion from the changed capacitor values to the changed electrical signals. The back-end dies 9-10 are memory dies, which are used to locally store the critical information processed by the front-end dies within the SoW and the external information sensed by the microphones. The back-end dies 11-12 are communication dies, which are used to transmit signals collected by the MEMS microphones to an external end in the form of the wireless signals. The power supply ports 25 thereon are provided with four voltage ports, which are +1.8V˜3.3V, +3.3V, +5V, and GND. The different back-end dies included in the SoW can provide differentiated functional definitions for the devices. For example, the photovoltaic dies convert the captured solar energy into the electrical energy and store it into the energy storage die under the command control from the energy management dies, where the photovoltaic dies work as the energy captured devices. The photovoltaic dies show the external light intensity/light power information by values of the output photocurrents and photovoltages under the command control from the photoelectric detection dies, where the photovoltaic dies works as the sensing devices.

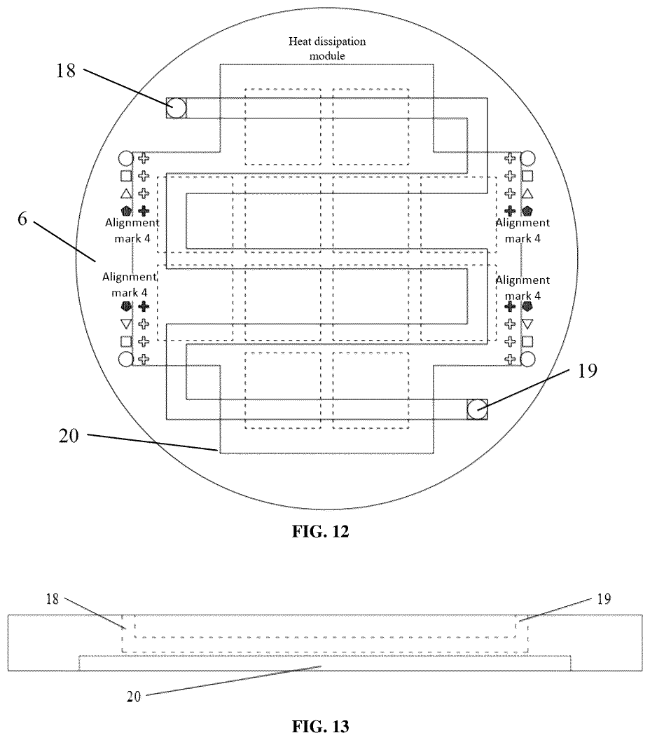

As shown in FIG. 12, FIG. 12 shows the schematic structure diagram of the wafer on the heat dissipation module layer in the wafer-level design, manufacturing, and integration methods of the SoW. The reference sign 6 represents the wafer on the heat dissipation module layer. The low temperature liquid is passed into the liquid cooling channel from the liquid inlet port 18, and flows out from the liquid outlet port 19 to cool down the high temperature region of the back-end dies. The recessed patterned groove 20 complementary on the back-end die on the heat dissipation module is the reserved space of the protrusion part on the back-end dies when the wafer 6 of the heat dissipation module bonds with the wafer 5 on the back-end dies layer by hot pressing method. At the same time, the thickness between the liquid cooling channel and the back-end die is reduced, so that the liquid-cooling heat dissipation is realized more efficiently. Such arrangement can be more specifically shown in FIG. 13 of the cross-section structure schematic diagram of the wafer on the heat dissipation module layer of the wafer-level design, manufacturing, and integration methods of the SoW. In the embodiment, the liquid inlet port 18 and the liquid outlet port 19 are connectors for letting the cooling liquid pass through, and are connected for liquid-cooling heat dissipation when the SoW operates at high temperature.

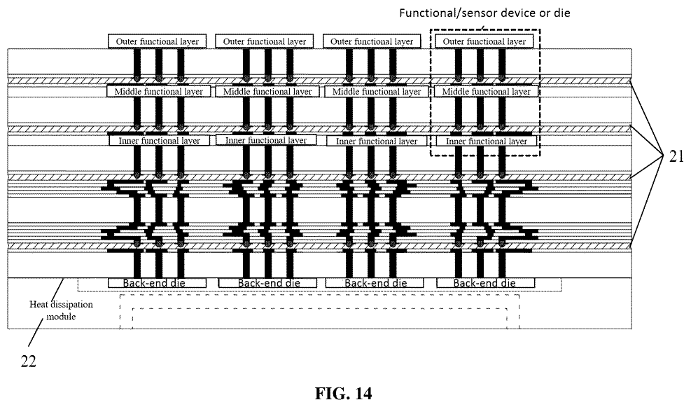

As shown in FIG. 14, FIG. 14 shows the cross-section structure schematic diagram of the SoW in the wafer-level design, manufacturing, and integration methods of the SoW. The reference sign 21 represents the plastic fill of the reflow soldering of the wafer interface, which is used to mechanically and electrically connect the solder ball of the upper wafer with the bonding pad of the lower wafer after the reflow soldering. To prevent the welding failure at the solder joint under ambient air conditions for a long time (metal contacts can be oxidized), the gaps between the wafers need to be filled with the epoxy molding compound (EMC).

The above shows only preferable embodiments of the present disclosure, and is not intended to limit the present disclosure. Any modifications, equivalent substitutions, improvements, etc. made within the spirit and principles of the present disclosure shall be included in the scope of protection of the present disclosure.

What is claimed is:

1. A wafer-level design, manufacturing, and integration method of a system on wafer (SoW), comprising:
an integrated functional/sensor devices (dies) bonding with multiple wafers, comprising a wafer (dies layer) with outer functional layer of the functional/sensor devices (dies), a wafer (dies layer) with middle functional layer of the functional/sensor devices (dies), and a wafer (dies layer) with inner functional layer of the functional/sensor devices (dies), wherein the wafers on an outer layer, a middle layer, and an inner layer bond into the functional/sensor devices (dies) with a high density, wherein the devices (dies) generated complete functions; an electrical interconnect layer, comprising RDLs on front and back surfaces and partitioned TSV arrays interconnect between the upper and lower surfaces; a back-end dies layer (wafer), comprising dies for computing, communication and storage, and power supply ports; and heat dissipation module layer, comprising serpentine liquid cooling channels, liquid cooling inlet/outlet ports, and a recessed patterned heat dissipation groove complementary on the back-end dies layer.

2. The wafer-level design, manufacturing, and integration method of the SoW according to claim 1, wherein complete functional/sensor devices (dies) which are difficult to be prepared on a single wafer is prepared on different wafers (layers) firstly; and then the functional/sensor devices (dies) with complete functions is realized by bonding and interconnecting of multiple wafers (layers), wherein after the outer functional layer, the middle functional layer, and the inner functional layer of the functional/sensor device (die) are designed in different wafers, partial structures in different functional/sensor devices (dies) are co-wafer fabricated by similar integrated circuit (IC) processes.

3. The wafer-level design, manufacturing, and integration method of the SoW according to claim 1, wherein a layout design in wafers of the outer functional layer, the middle functional layer, and the inner functional layer of the functional/sensor devices (dies) is not limited to three wafers (layers), wherein the number of functional wafers (layers) is different according to a complexity of functions or a complexity of an internal structure of different functional/sensor devices (dies); and at the same time, the number of functional wafers (layers) can be designed differentially according to differences of preparation difficulty of an internal structure of the functional/sensor devices (dies).

4. The wafer-level design, manufacturing, and integration method of the SoW according to claim 1, wherein a structure on only one of the outer functional wafer (layer), the middle functional layer, and the inner functional layer of the functional/sensor devices (dies) cannot realize complete functions of devices (dies); and complete functions of devices can be realized by electrically connecting the partial structures/devices in the outer functional layer, the middle functional layer, and (or) the inner functional layer via bonding by TSV, RDL, and Bumps.

5. The wafer-level design, manufacturing, and integration method of the SoW according to claim 1, wherein the outer functional wafer (layer) of the functional/sensor devices (dies) is provided with external structures of a plurality of functional/sensor devices (dies), comprising functional/sensor structures (parts) that have information interaction or energy conversion/transfer with the external environments.

6. The wafer-level design, manufacturing, and integration method of the SoW according to claim 1, wherein the middle functional wafer (layer) of the functional/sensor devices (dies) comprises a critical structure layer (wafer) of the functional/sensor devices (dies) for processing electrical signals generated by the outer functional layer; analog signal processing circuits comprising an amplifier, a filter, and an oscillator; digital signal processing circuits comprising a logic gate, a memory, and a counter; or partial other structures of the functional/sensor devices (dies).

7. The wafer-level design, manufacturing, and integration method of the SoW according to claim 1, wherein the inner functional wafer (layer) of the functional/sensor devices (dies) is the other structures required to realize devices' (dies') functions besides the outer functional layer and the middle functional layer, and is taken as a complement to a functional layer structure, comprising structures that cannot be co-wafer prepared due to incompatibility of preparation processes within the outer functional layer and the middle functional layer.

8. The wafer-level design, manufacturing, and integration method of the SoW according to claim 1, wherein on the outer functional layer (wafer), the middle functional layer (wafer), and the inner functional layer (wafer) of the functional/sensor devices (dies), dummy dies are arranged on four vertexes furthest away from a geometric center of the layers (wafers), and are configured to balance internal forces generated by warping of the layers (wafers), to provide flat boding sites with large area.

9. The wafer-level design, manufacturing, and integration method of the SoW according to claim 1, wherein the electrical interconnect layer (wafer) comprises RDLs on upper and lower surfaces and TSV arrays, wherein the RDLs on double surfaces are configured to electrically interconnect the double surfaces of the wafer horizontally and fan out fine circuit contacts of dies to provide more pins and larger I/O contact space; and the TSV arrays realize electrical interconnections in a vertical direction between two surfaces, and an electrical interconnection of any two points in the wafer on the electrical interconnect layer can be realized (through TSV arrays) in conjunction with the RDLs on the double surfaces.

10. The wafer-level design, manufacturing, and integration method of the SoW according to claim 1, wherein the back-end dies comprise CPU, GPU, and MCU, and the back-end dies are configured as main controlling dies to send out commands via the electrical interconnect layer, and to invoke one or more functional/sensor devices (dies) or structures on the outer functional layer, the middle functional layer, and the inner functional layer to realize reconfiguration of functions, wherein different functional/sensor devices (dies) can achieve different functions under different commands from the different back-end dies.

11. The wafer-level design, manufacturing, and integration method of the SoW according to claim 10, wherein the functional/sensor devices (dies) can be functionally defined by the back-end dies according to a certain timing logic, and the same functional/sensor devices (dies) perform different functions under different commands from the different back-end dies, to realize functions reconfiguration under a collaboration of multiple devices (dies) in the SoW.

12. The wafer-level design, manufacturing, and integration method of the SoW according to claim 1, wherein the heat dissipation module wafer (layer) comprises connectors of the serpentine liquid cooling channels and the liquid inlet/outlet ports, and the recessed patterned groove complementary on the back-end dies, wherein the liquid cooling channel connectors comprise liquid inlet ports and liquid outlet ports, in which a low-temperature liquid flows through to cool down the high temperature generated by the operation of back-end dies.

13. The wafer-level design, manufacturing, and integration method of the SoW according to claim 1, wherein bonding and interconnection of multi-wafers comprise solder balls, UBM (under bump metallization), and EMC (epoxy molding compound), wherein after multiple wafers are aligned by alignment marks, solder balls on bottom of an upper wafer are stably interconnected with bonding pads on upper surface of a lower wafer electrically and mechanically via reflow soldering, wherein surfaces of the wafers need to perform UBM before planting the solder balls to increase adhesion of the tin solder to the wafers and to prevent tin diffusing into the wafers.
